(19) United States
(12) Patent Application Publication
(10) Pub. No.: US 2025/0112021 A1
(43) Pub. Date: Apr. 3, 2025

(54) CRYO-ELECTRON MICROSCOPY IMAGE PROCESSING METHOD AND APPARATUS, TERMINAL, AND STORAGE MEDIUM

(71) Applicants: Beijing Youzhuju Network Technology Co., Ltd., Beijing (CN); Lemon Inc., Grand Cayman (KY)

(72) Inventors: Jing YUAN, Beijing (CN); Yi ZHOU, Beijing (CN); Yilai LI, Los Angeles, CA (US); Quanquan GU, Los Angeles, CA (US); Fei YE, Beijing (CN)

(21) Appl. No.: 18/891,450

(22) Filed: Sep. 20, 2024

(30) Foreign Application Priority Data
Sep. 28, 2023 (CN) 202311274360.6

(51) Int. Cl. H01J 37/22; G06T 7/73; H01J 37/26

(52) U.S. Cl. CPC H01J 37/222; G06T 7/73; H01J 37/261; G06T 2207/10056; H01J 2237/2001; H01J 2237/223

(57) ABSTRACT

The present disclosure provides a cryo-electron microscopy image processing method and apparatus, a terminal, and a storage medium. The cryo-electron microscopy image processing method includes: obtaining a cryo-electron microscopy image; encoding the cryo-electron microscopy image into latent variables through an encoder; converting the latent variables into an atomic model structure through a decoder; correcting the atomic model structure using a loss function to obtain a corrected atomic model structure, where the loss function includes a bond length constraint loss function, a clash constraint loss function, and a spring constraint loss function; and converting, through a projector module, the corrected atomic model structure into a density map represented by Gaussian spheres, and projecting the density map to obtain a projection image.

### CROSS-REFERENCE TO RELATED APPLICATION(S)

This application claims priority to Chinese Application No. 202311274360.6 filed Sep. 28, 2023, the disclosure of which is incorporated herein by reference in its entirety.

### FIELD

The present disclosure relates to the technical field of information, and in particular to a cryo-electron microscopy image processing method and apparatus, a terminal, and a storage medium.

### BACKGROUND

Cryo-electron microscopy technique, which has become popular and grown stronger in the past two decades, is a biological macromolecular structure analysis technique that can analyze a structure including dynamic and difficult-to-crystallize biological macromolecular complexes. Cryo-electron microscopy is a microscopic technique that uses a transmission electron microscope to observe a sample at a low temperature. By freezing the sample (a protein is constantly moving at room temperature) and placing the sample at a low temperature inside the microscope, a highly coherent electron beam is used as a light source, and some electrons will be scattered by heavy atoms in the sample when the electron beam passes through the sample and nearby ice layers. These scattering signals are imaged and recorded by a detector and a lens system, and are finally processed into a projection image, thereby obtaining a sample structure.

The signal-to-noise ratio of a cryo-electron microscopy image is very low, typically in the order of 0.001-0.0001. For an atomic model with an extremely high degree of freedom, if a solution space is not restricted, the model can easily fit into noise. Existing multi-conformational analysis work based on the atomic model typically restricts the solution space by performing normal mode analysis (NMA) on an atomic structure in advance. However, NMA itself is highly limited by an initial state structure used for analysis and is suitable for modeling local vibrations of proteins near a steady state. Therefore, it is desirable to develop a method that can accurately and efficiently analyze a dynamic conformation of the cryo-electron microscopy image of the protein.

### SUMMARY

In order to solve the existing problems, the present disclosure provides a cryo-electron microscopy image processing method and apparatus, a terminal, and a storage medium.

The present disclosure uses the following technical solutions.

An embodiment of the present disclosure provides a cryo-electron microscopy image processing method. The cryo-electron microscopy image processing method includes: obtaining a cryo-electron microscopy image; encoding the cryo-electron microscopy image into latent variables through an encoder; converting the latent variables into an atomic model structure through a decoder; correcting the atomic model structure using a loss function to obtain a corrected atomic model structure, where the loss function includes a bond length constraint loss function, a clash constraint loss function, and a spring constraint loss function; and converting, through a projector module, the corrected atomic model structure into a density map represented by Gaussian spheres, and projecting the density map to obtain a projection image.

Another embodiment of the present disclosure provides a cryo-electron microscopy image processing apparatus. The control apparatus includes: an image obtaining module, configured to obtain a cryo-electron microscopy image; an encoding module, configured to encode the cryo-electron microscopy image into latent variables through an encoder; a decoding module, configured to convert the latent variables into an atomic model structure through a decoder; a correction module, configured to correct the atomic model structure using a loss function to obtain a corrected atomic model structure, where the loss function includes a bond length constraint loss function, a clash constraint loss function, and a spring constraint loss function; and a projection module, configured to convert, through a projector module, the corrected atomic model structure into a density map represented by Gaussian spheres, and project the density map to obtain a projection image.

In some embodiments, the present disclosure provides a terminal, including at least one memory and at least one processor, where the memory is used to store program code, and the processor is used to invoke the program code stored in the memory to perform the above cryo-electron microscopy image processing method.

In some embodiments, the present disclosure provides a storage medium, where the storage medium is used to store program code, and the program code is used to perform the above cryo-electron microscopy image processing method.

According to the present disclosure, the atomic model structure is corrected using the loss function. Structural constraints are achieved through a bond length constraint and a clash constraint, such that all Gaussian spheres in a Gaussian density representation are in one-to-one correspondence with all amino acids of a protein. An atomic modeling structure at an amino acid level is directly introduced into three-dimensional reconstruction of a cryo-electron microscopy. In addition, the function of maintaining the stability of a local structure can be achieved through a spring constraint, thereby significantly reducing a solution space, and achieving more efficient and accurate multi-conformation analysis.

### BRIEF DESCRIPTION OF THE DRAWINGS

The above and other features, advantages, and aspects of various embodiments of the present disclosure will become more apparent in conjunction with the accompanying drawings and with reference to following specific implementations. Throughout the accompanying drawings, the same or similar reference numerals denote the same or similar elements. It should be understood that the accompanying drawings are illustrative, and components and elements may not necessarily be drawn to scale.

FIG. 1 is a flowchart of a cryo-electron microscopy image processing method according to an embodiment of the present disclosure.

FIG. 2 illustrates a Gaussian density representation and a projection of a protein according to an embodiment of the present disclosure.

FIG. 3 is a schematic flowchart of a cryo-electron microscopy image processing method according to an embodiment of the present disclosure.

FIG. 4 is an example constraint method for an atomic model structure of a protein according to an embodiment of the present disclosure.

FIG. 5 illustrates an example determining method for the cutoff frequency for low-frequency filtering according to an embodiment of the present disclosure.

FIG. 6 illustrates dynamic correction of a spring constraint according to an embodiment of the present disclosure.

FIG. 7 illustrates an atomic model structure and a projection of a protein analyzed using different methods.

FIG. 8 illustrates part of modules of a cryo-electron microscopy image processing apparatus according to another embodiment of the present disclosure.

FIG. 9 is a structural schematic diagram of an electronic device according to an embodiment of the present disclosure.

### DETAILED DESCRIPTION OF EMBODIMENTS

The embodiments of the present disclosure will be described in more detail below with reference to the accompanying drawings. Although the accompanying drawings show some embodiments of the present disclosure, it should be understood that the present disclosure may be implemented in various forms, and should not be construed as being limited to the embodiments stated herein. On the contrary, these embodiments are provided for a more thorough and complete understanding of the present disclosure. It should be understood that the accompanying drawings and the embodiments of the present disclosure are for exemplary purposes only, and are not intended to limit the scope of protection of the present disclosure.

It should be understood that the steps recorded in the method implementations in the present disclosure may be performed in different orders and/or in parallel. In addition, additional steps may be included and/or the execution of the illustrated steps may be omitted in the method implementations. The scope of the present disclosure is not limited in this aspect.

The term “including” used herein and variations thereof are open-ended inclusions, namely “including but not limited to”. The term “based on” is interpreted as “at least partially based on”. The term “an embodiment” means “at least one embodiment”; the term “another embodiment” means “at least one additional embodiment”; and the term “some embodiments” means “at least some embodiments”. Related definitions of other terms will be given in the description below.

It should be noted that concepts such as “first” and “second” mentioned in the present disclosure are only used to distinguish different apparatuses, modules, or units, and are not used to limit the order or relation of interdependence of functions performed by these apparatuses, modules, or units.

It should be noted that the modification of “a” mentioned in the present disclosure is illustrative rather than limiting, and those skilled in the art should understand that unless otherwise explicitly specified in the context, it should be interpreted as “one or more”.

The names of messages or information exchanged between a plurality of apparatuses in the implementations of the present disclosure are provided for illustrative purposes only, and are not used to limit the scope of these messages or information.

Proteins are not static in solution. At the moment of freezing, some transient protein conformations are also recorded. Therefore, a single-particle cryo-electron microscopy can not only analyze several low-energy conformations of a protein but also have the potential to analyze transient conformations between the low-energy conformations. In an cryo-electron microscopy image, each dataset includes many 2D projections from one or more 3D structures in potential different conformational states. Therefore, the datasets of the cryo-electron microscopy image may include rich heterogeneity information at a conformational level. However, existing cryo-electron microscopy methods have not fully exploited conformational information “hidden” within a vast amount of cryo-electron microscopy projection data.

For the problem about the multi-conformation analysis of the cryo-electron microscopy in a given projection direction, the goal is to determine a conformational category of each projection image (particle). A density map generally refers to a three-dimensional object directly reconstructed via the cryo-electron microscopy image through back-projection. For real cryo-electron microscopy data, the number of conformational categories within the data is unknown. Protein motions are not abrupt, and multi-conformational analysis should be continuous, which is the reason for generative modeling.

Some existing methods adopt an encoder-decoder network to predict an NMA coefficient of conformational changes. According to the methods, some bases of different motion modes are obtained by performing NMA on a reference structure (a given initial structure) in advance. A model predicts linear combination parameters of these bases to represent the conformational changes of the structure itself. The methods have the defects that the NMA strongly relies on the initial structure, and the bases of the motion modes are some oscillations near the initial structure. The number of the NMA bases also needs to be manually selected. Moreover, the methods only work on simulated data and cannot be applied to real cryo-electron microscopy data.

The present disclosure provides a method based on regularization of an atomic model. By maintaining the stability of a local structure, an algorithm search space is significantly reduced. Meanwhile, biases from an initial atomic structure are avoided through the means of adaptive relaxation, and a generative model may directly output reasonable atomic model dynamics at an amino acid level. Therefore, using atomic model information may assist in analyzing dynamic conformations in the cryo-electron microscopy data. During analyzing conformational dynamics of the protein density map, a reasonable protein backbone model that includes dynamics may also be provided.

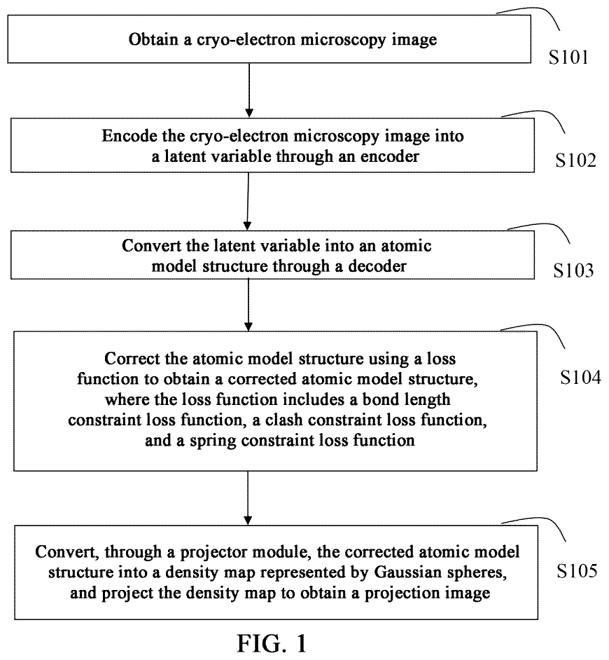

FIG. 1 provides a flowchart of a cryo-electron microscopy image processing method according to an embodiment of the present disclosure. The cryo-electron microscopy image processing method in the present disclosure may include: Step S101: Obtain a cryo-electron microscopy image. The cryo-electron microscopy image is an image captured by a cryo-electron microscope. When a protein structure is analyzed using the cryo-electron microscope, the cryo-electron microscopy image of a protein is first obtained. In some embodiments, the cryo-electron microscopy image is the cryo-electron microscopy image of the protein.

In some embodiments, the method in the present disclosure may further include: Step S102: Encode the cryo-electron microscopy image into latent variables through an encoder. In some embodiments, the encoder is a multi-layer neural network that encodes the input cryo-electron microscopy image with a low signal-to-noise ratio into low-dimensional latent variables. In some embodiments, the latent variables include an 8-dimensional vector. In some embodiments, the latent variables imply conformational information of the protein. By analyzing a latent space determined by these latent variable vectors, multi-conformational analysis of the data is achieved.

In some embodiments, the method in the present disclosure may further include: Step S103: Convert the latent variables into an atomic model structure through a decoder. In some embodiments, the decoder is a multi-layer neural network that converts the latent variables into different conformations, specifically the atomic model structure. In some embodiments, the atomic model structure includes a matrix shaped like N×3, where N refers to the number of amino acids, and 3 refers to coordinates (x, y, z) of each amino acid.

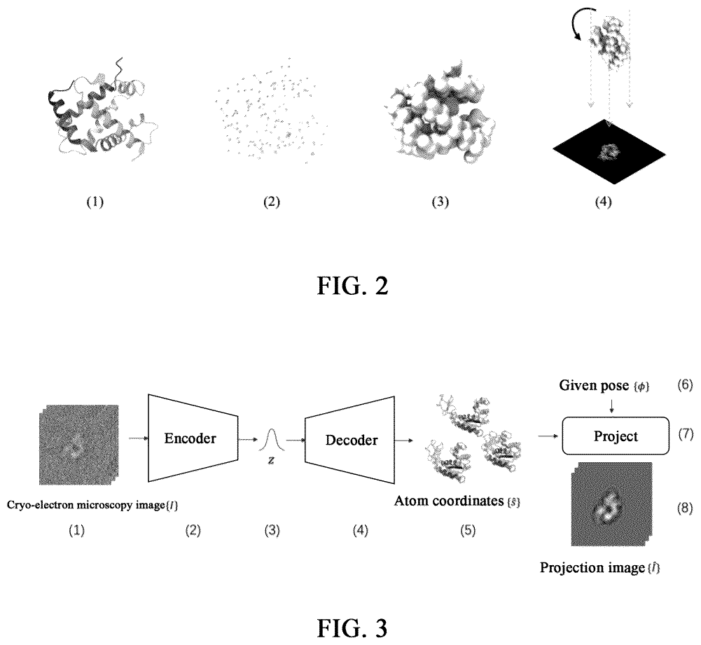

To facilitate understanding, a Gaussian density representation and projection of the protein are described below with reference to FIG. 2. As shown in (1) of FIG. 2, a protein is formed by folding amino acids on a single chain. As shown in (2) of FIG. 2, amino acids are used as basic units and used to represent a protein as nodes, and the nodes are connected in pair to form a chain structure. As shown in (3) of FIG. 2, a three-dimensional Gaussian distribution is constructed with the node as the center and the total number of electrons in the amino acid as the intensity, representing the potential density of the protein to obtain the Gaussian density representation of the protein. In some embodiments, the Gaussian density representation is assigned by isotropic Gaussian values. A Gaussian sphere of each amino acid is centered on a C-alpha atom of the amino acid, and has assignment positively correlated with the total number of electrons of all atoms composing the amino acid. The variance is manually set, typically to 2, resulting in a density map represented by Gaussian spheres. As shown in (4) of FIG. 2, given the potential density of a protein, according to the pose of the protein, a projection image may be obtained by projecting in a z-axis direction.

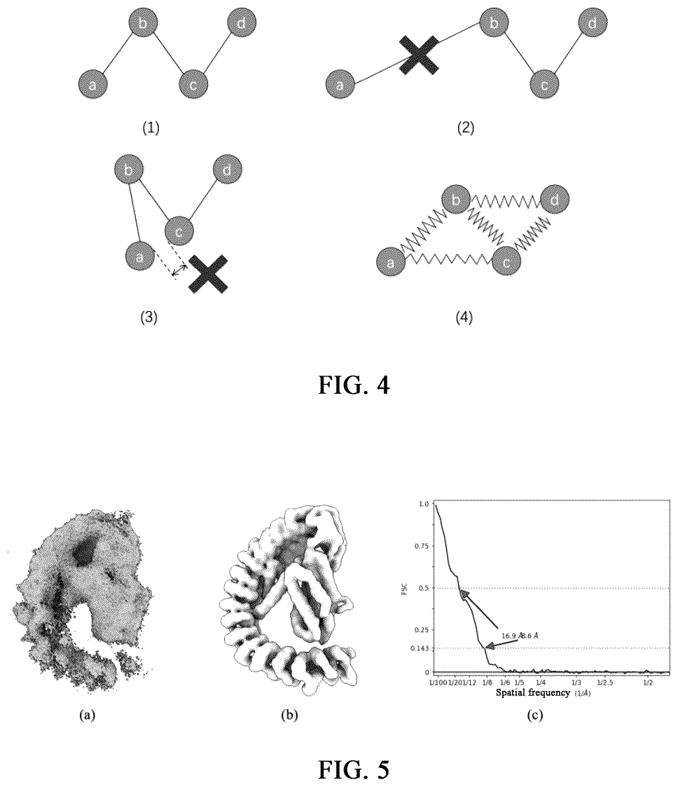

In some embodiments, the method in the present disclosure may further include: Step S104: Correct the atomic model structure using a loss function to obtain a corrected atomic model structure, where the loss function includes a bond length constraint loss function, a clash constraint loss function, and a spring constraint loss function. In some embodiments, the bond length constraint loss function, the clash constraint loss function, and the spring constraint loss function correspond to a bond length constraint, a clash constraint, and a spring constraint of the atomic model structure of the protein respectively. FIG. 4 illustrates an example constraint method for an atomic model structure of a protein according to an embodiment of the present disclosure. In FIG. 4, (1) represents a reference protein structure, with a, b, c, and d denoting example amino acids. In FIG. 4, (2) represents a bond length constraint example, which requires that a distance between adjacent amino acids of a protein structure is kept as a constant. In (2) of FIG. 4, an edge between a and b is stretched, violating the bond length constraint. The bond length may be shortened through the bond length constraint loss function. In some embodiments, assuming that a certain bond length of a predicted protein structure is \hat{d}_{bond}, a mathematical form of constraint is [symbol] _{bond}=∥\hat{d}_{bond}−3.8∥², where 3.8 Å represents a distance between C-alpha of two adjacent amino acids on a protein chain. In FIG. 4, (3) represents a clash constraint example, which requires that a distance between non-adjacent amino acids of the protein structure should not be too close, and may be pushed further apart through the constraint loss function. In (3) of FIG. 4, a and c represent an example that does not satisfy the clash constraint. In some embodiments, assuming that a distance between two amino acids of the predicted protein structure is \hat{d}_{clash}, a mathematical form of constraint is [symbol] _{clash}=∥min(4, \hat{d}_{clash})−4∥². In FIG. 4, (4) is an example of a spring constraint. Through the spring constraint, a “spring”-like constraint is established between amino acids within a certain distance threshold. The “spring” effect is that regardless of the distance between adjacent amino acids being “stretched” or “compressed”, an opposite acting force is generated to resist such changes. In some embodiments, the spring constraint is only constructed within the same amino acid chain, and not between chains. In some embodiments, assuming that a distance between two amino acids of the predicted protein structure is \hat{d}, a distance of a reference structure is d, and a mathematical form of constraint is [symbol] _{EN}=∥\hat{d}−d∥².

In some embodiments, the bond length constraint loss function L_{cont} ensures integrity of connection between two adjacent residues. The bond length constraint loss function L_{cont} is expressed as:

$${ℒ}_{cont} = \frac{1}{N - 1} {\sum }_{i}^{N - 1} {‖ {\hat{d}}_{i , i + 1} - {d}_{i , i + 1} ‖}^{2} ,$$

d_{i,i+1} represents a distance between two adjacent residues of the reference protein structure, and \hat{d}_{i,i+1} represents a predicted distance between the same pair of residues.

In some embodiments, to prevent clash between two residues after predicted deformation, the clash constraint loss function L_{clash} for the two residues is calculated as follows:

$${P}_{clash} = \{ ( i , j ) \vert 1 \leq i , j \leq N ; \vert i - j \vert > 1 ; {\hat{d}}_{ij} < {k}_{clash} \} , \\ {ℒ}_{clash} = \frac{1}{\vert {P}_{clash} \vert} {\sum }_{( i , j ) ∈ {P}_{clash}} {‖ {\hat{d}}_{ij} - {k}_{clash} ‖}^{2} .$$

P_{clash} refers to a set of clash residue pairs during training, (i, j) is a number of a residue in the structure, and \hat{d}_{i,j} represents a predicted distance between two non-adjacent residues. When the two non-adjacent residues are closer than a length K_{clash}, two non-adjacent residues receive corresponding penalties or reverse compensation to prevent residue clash, where K_{clash} is 4 angstroms.

In some embodiments, to maintain rigidity of a local structure, the spring constraint loss function L_{EN} is adopted, and L_{EN} is calculated as follows:

$${P}_{EN} = \{ ( i , j ) \vert 1 \leq i \leq N ; j ∈ {𝒩}_{i} ; \vert i - j \vert > 1 \} , {𝒩}_{i} = \{ j \vert {d}_{ij} < {k}_{EN} \} . \\ {ℒ}_{EN} = \frac{1}{\vert {P}_{EN} \vert} {\sum }_{( i , j ) ∈ {P}_{EN}} {‖ {\hat{d}}_{ij} - {d}_{ij} ‖}^{2} ,$$

(i ,j) is a number or index pair in a spring network P_{EN}. For each residue with the index i, [symbol] defines a set of adjacent indices with pairwise distances d_{i,j} in the reference structure, where k_{EN} is a constant of 12 angstroms, and \hat{d}_{i,j}, d_{i,j} represent distances between centers of two residues in a predicted structure and a reference atomic model structure respectively.

In some embodiments, structural constraints are achieved through the bond length constraint and the clash constraint, such that all Gaussian spheres in the Gaussian density representation are in one-to-one correspondence with all amino acids of the protein. Atomic modeling at the amino acid level is directly introduced into three-dimensional reconstruction of the cryo-electron microscopy. In addition, the function of maintaining the stability of the local structure is achieved through the spring constraint, thereby significantly reducing the search space or solution space and achieving more efficient and accurate multi-conformation analysis.

In some embodiments, the method in the present disclosure may further include: Step S105: Convert, through a projector module, the corrected atomic model structure into a density map represented by Gaussian spheres, and project the density map to obtain a projection image. In some embodiments, the projector module is an integration module for ternary Gaussian distribution, which converts the atomic model structure into a density map represented by Gaussian spheres and completes projection at a given projection perspective, thereby obtaining a noise-free output projection image. It should be understood that the projector module is commonly used and known, and the projection process is unrelated to machine learning, with no parameters to be learned. FIG. 3 illustrates a schematic flowchart of a cryo-electron microscopy image processing method according to an embodiment of the present disclosure. An overall framework of a model is of a variational autoencoder (VAE) structure. The main purpose of cryo-electron microscopy image reconstruction is to reconstruct a 3D object V∈ [symbol] ^{D×D×D} from a 2D projection {I⁽ⁱ⁾∈ [symbol] ^{D×D}|i=1, 2, . . . M}, where D represents a side length of an image, and M represents a size of a dataset. In FIG. 3, (1) represents a cryo-electron microscopy image (i.e., an input image I⁽ⁱ⁾∈ [symbol] ^{D×D}. The cryo-electron microscopy image is encoded into a latent variable (3) through an encoder (2), that is, the function of the encoder is [symbol] ^{D×D}→ [symbol] ^{|z|}. The latent variable is converted into an atomic model structure (5) through a decoder (4) (i.e., the atomic model structure S∈ [symbol] ^{N×3} of the protein is derived through a VAE-based deformation prediction network that includes the encoder and the decoder), that is, the function of the decoder is [symbol] ^{|z|}→ [symbol] ^{N×3}, where N is the number of amino acids, and 3 corresponds to coordinates (x, y, z) of the corresponding amino acid. Both the encoder and the decoder are multilayer neural networks (MLPs), and the MLP is a global feature extractor. Hidden dimensions of the encoder and the decoder are set to (512, 256, 128, 64, 32) and (32, 64, 128, 256, 512) respectively, and the size of the latent space is 8. Then, the atomic model structure is corrected through the loss function. The projector module (7) may convert the corrected atomic model structure into a density map represented by Gaussian spheres (i.e., a volumetric representation V∈ [symbol] ^{D×D×D}) and project the density map under a given pose (6) to obtain a projection image Î⁽ⁱ⁾∈ [symbol] ^{D×D} (8).

For dynamic single-particle cryo-electron microscopy image data with a low signal-to-noise ratio, due to a huge potential structural search space, it is difficult for existing methods to find a correct conformational space to reconstruct dynamic changes. The present disclosure introduces prior information from the atomic model structure through reasonable regularization terms of the loss function, reduces the structural search space, and achieves more efficient and accurate multi-conformational analysis, thereby obtaining smooth and reasonable dynamics. When continuous conformations are analyzed from the cryo-electron microscopy data, the existing methods can only obtain a series of protein density maps including dynamics, and for a reasonable atomic model structure, subsequent tedious manual modeling and adjustment are required. The present disclosure uses the Gaussian spheres to correlate the atomic model with the corresponding density map. Through the bond length constraint and the clash constraint, the Gaussian spheres correspond to the amino acid coordinates, such that the reasonable and dynamic atomic model at the amino acid level can be directly obtained using the generative model. The structural constraints are achieved through the bond length constraint and the clash constraint, such that all Gaussian spheres in the Gaussian density representation are in one-to-one correspondence with all amino acids of the protein. Atomic modeling at the amino acid level is directly introduced into three-dimensional reconstruction of the cryo-electron microscopy. In addition, the function of maintaining the stability of the local structure is achieved through the spring constraint, thereby significantly reducing the search space or solution space and achieving more efficient and accurate multi-conformation analysis.

In some embodiments, the loss function further includes a reconstruction loss function, which is determined based on a mean squared error between the cryo-electron microscopy image and the projection image. In some embodiments, the cryo-electron microscopy image processing method further includes: performing low-frequency filtering on the cryo-electron microscopy image and the projection image before determining the reconstruction loss function. The method in the present disclosure is only used to fit low-frequency signals in original image data, such that consistent low-frequency filtering is performed on an input image and an output image before calculating a similarity loss function of the input image and the output image. In some embodiments, the low-frequency signals in the cryo-electron microscopy image are sufficient to capture large dynamics of the protein conformation. In the present disclosure, a coarse-grained atomic model (Gaussian spheres centered on C-alpha at the amino acid level) are adopted along with the low-frequency filtering of the image, only the low-frequency signals in the image are fitted, thereby avoiding the defects of modeling the cryo-electron microscopy density map with the Gaussian spheres.

In some embodiments, the cutoff frequency for low-frequency filtering is determined based on the Fourier shell correlation (FSC) between a reconstruction result of the cryo-electron microscopy image and the density map. In some embodiments, the cutoff frequency for low-frequency filtering is determined by calculating the Fourier shell correlation (FSC) between a reconstruction result of conventional cryo-electron microscopy software (e.g., EMAN2) and the Gaussian density map. FIG. 5 illustrates an example determining method for the cutoff frequency for low-frequency filtering according to an embodiment of the present disclosure. In FIG. 5, (a) represents a reconstructed density map using conventional software EMAN2, (b) represents a Gaussian density map, (c) shows the FSC calculation between (a) and (b). Taking 0.5 as a threshold (a correlation coefficient of signals lower than a certain frequency is higher than 0.5), the cutoff frequency is determined to be 1/16.9.

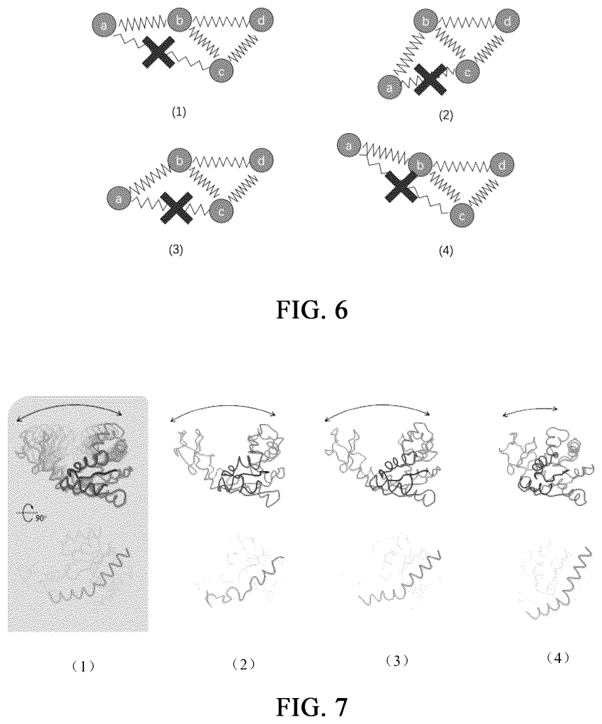

In some embodiments, the cryo-electron microscopy image processing method in the present disclosure further includes: calculating variances of lengths of springs between amino acids when the atomic model structure is corrected using the spring constraint loss function, and discarding springs with the variances that fall within a preset percentage when the variances are sorted in descending order. This is a dynamic correction method for the spring constraint based on the variance. In some embodiments, the preset percentage is 5%. In FIGS. 6, (1), (2), (3), and (4) are four different structures predicted by the model, where the variance of the length of the edge a-c is the largest, and the variances of the lengths of the other edges are relatively small. The edges with the large variance may be caused by protein dynamics, meaning that the movement range of the amino acid (a) is relatively large, leading to drastic changes in the length of a-c. Therefore, the spring constraint of the edge a-c may be discarded based on a prediction result. In some embodiments, for n springs (one spring is formed between two amino acids, and it should be understood that the spring is not a physical spring, but rather a hypothetical spring or a connection between two amino acids that is similar to a force formed by the spring), the variance of the length of each spring is calculated, and then the springs with the largest variance of 5% (i.e., those in the top 5% when the variances are sorted in descending order) are discarded. The variance-based adaptive spring correction achieves automatic relaxation of the spring constraint, which is beneficial to promoting more accurate conformational analysis, thereby obtaining smooth and reasonable dynamic conformations, thereby maintaining most of local structures, and avoiding falling into an energy minimum of an initial structure.

In some embodiments, too weak constraints allow for free searching of atomic models in the search space, but cannot maintain the stability of local structures, and as a result, analyzed conformations are far from an original protein conformation. On the other hand, if the constraints are too strong, the atomic model structure will be trapped vibrating near a low-energy state of an initial protein structure. By utilizing the automatic relaxation of the spring constraint, protein conformation analysis can be performed more accurately. In FIG. 7, (1) illustrates a closed initial state of a protein. In FIG. 7, (2) illustrates an atomic model structure analyzed by a commonly used weak constraint model that only enforces backbone continuity, as well as a projection thereof. It can be seen that a local structure of a well-folded protein (e.g., α-helix) is destroyed. In FIG. 7, (3) illustrates an atomic model structure using an adaptive spring correction constraint method, as well as a projection thereof, which successfully reconstructs an open state of the protein. In FIG. 7, (4) illustrates an atomic model structure using a commonly used NMA-based model, as well as a projection thereof. An interlocking problem of the NMA-based model (adjacent nodes of the initial structure tend to be kept in a base direction, forcing a large energy barrier from the closed state to the open state) hinders the NMA-based model from analyzing the transition from closed to open.

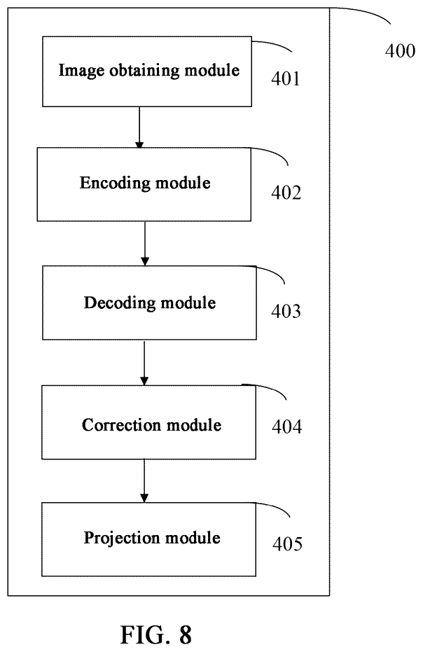

An embodiment of the present disclosure further provides a cryo-electron microscopy image processing apparatus 400. FIG. 8 illustrates a cryo-electron microscopy image processing apparatus 400 according to some embodiments. The cryo-electron microscopy image processing apparatus 400 includes an image obtaining module 401, an encoding module 402, a decoding module 403, a correction module 404, and a projection module 405. In some embodiments, the image obtaining module 401 is configured to obtain a cryo-electron microscopy image. In some embodiments, the encoding module 402 is configured to encode the cryo-electron microscopy image into latent variables through an encoder. In some embodiments, the decoding module 403 is configured to convert the latent variables into an atomic model structure through a decoder. In some embodiments, the correction module 404 is configured to correct the atomic model structure using a loss function to obtain a corrected atomic model structure, where the loss function includes a bond length constraint loss function, a clash constraint loss function, and a spring constraint loss function. In some embodiments, the projection module 405 is configured to convert, through a projector module, the corrected atomic model structure into a density map represented by Gaussian spheres, and project the density map to obtain a projection image.

It should be understood that the description content of the cryo-electron microscopy image processing method is also applicable to the cryo-electron microscopy image processing apparatus 400 herein. For simplicity, no detailed description will be given herein.

In some embodiments, the latent variables include an 8-dimensional vector. In some embodiments, the atomic model structure includes an N×3 matrix, where N corresponds to the number of amino acids, and 3 corresponds to spatial coordinates (x, y, z) of the corresponding amino acid. In some embodiments, the loss function further includes a reconstruction loss function, which is determined based on a variance between the cryo-electron microscopy image and the projection image. In some embodiments, the cryo-electron microscopy image processing apparatus further includes: a filtering module, configured to perform low-frequency filtering on the cryo-electron microscopy image and the projection image before determining the reconstruction loss function. In some embodiments, the cutoff frequency for low-frequency filtering is determined based on the Fourier shell correlation between a reconstruction result of the cryo-electron microscopy image and the density map. In some embodiments, the correction module is further configured to: calculate variances of lengths of springs between amino acids when the atomic model structure is corrected using the spring constraint loss function, and discard springs with the variances that fall within a preset percentage when the variances are sorted in descending order.

In addition, the present disclosure further provides a terminal, including at least one memory and at least one processor, where the memory is used to store program code, and the processor is used to invoke the program code stored in the memory to perform the above cryo-electron microscopy image processing method.

In addition, the present disclosure further provides a computer storage medium. The computer storage medium stores program code. The program code is used to perform the above cryo-electron microscopy image processing method.

The above is a description of the cryo-electron microscopy image processing method and apparatus of the present disclosure based on the embodiments and application examples. In addition, the present disclosure further provides a terminal and a storage medium. The terminal and the storage medium are described below.

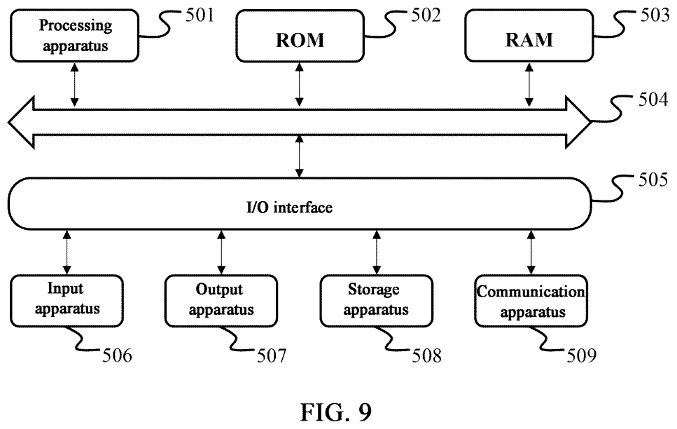

Referring to FIG. 9 below, FIG. 9 illustrates a structural schematic diagram of an electronic device (e.g., a terminal device or a server) 500 suitable for implementing an embodiment of the present disclosure. The terminal device in this embodiment of the present disclosure may include, but is not limited to, mobile terminals such as a mobile phone, a notebook computer, a digital broadcast receiver, a personal digital assistant (PDA), a portable Android device (PAD), a portable media player (PMP), and a vehicle-mounted terminal (e.g., a vehicle navigation terminal), and fixed terminals such as a digital TV and a desktop computer. The electronic device shown in FIG. 9 is merely an example, and shall not impose any limitation on the function and scope of use of the embodiments of the present disclosure.

As shown in FIG. 9, the electronic device 500 may include a processing apparatus (e.g., a central processing unit and a graphics processing unit) 501, which may perform various suitable actions and processes based on a program stored in a read-only memory (ROM) 502 or a program loaded from a storage apparatus 508 into a random access memory (RAM) 503. The RAM 503 further stores various programs and data needed by the operation of the electronic device 500. The processing apparatus 501, the ROM 502, and the RAM 503 are connected to one another through a bus 504. An input/output (I/O) interface 505 is also connected to the bus 504.

Typically, the following apparatuses may be connected to the I/O interface 505: an input apparatus 506, including, for example, a touchscreen, a touchpad, a keyboard, a mouse, a camera, a microphone, an accelerometer, and a gyroscope; an output apparatus 507, including, for example, a liquid crystal display (LCD), a speaker, and a vibrator; the storage apparatus 508, including, for example, a magnetic tape and a hard drive; and a communication apparatus 509. The communication apparatus 509 may allow the electronic device 500 to be in wireless or wired communication with other devices for data exchange. Although FIG. 9 illustrates the electronic device 500 with various apparatuses, it should be understood that it is not necessary to implement or have all the shown apparatuses. It may be an alternative to implement or have more or fewer apparatuses.

Particularly, the foregoing process described with reference to the flowcharts according to the embodiments of the present disclosure may be implemented as a computer software program. For example, an embodiment of the present disclosure includes a computer program product including a computer program carried on a computer-readable medium. The computer program includes program code for performing the method shown in the flowchart. In this embodiment, the computer program may be downloaded and installed from the network through the communication apparatus 509, or installed from the storage apparatus 508, or installed from the ROM 502. The computer program, when executed by the processing apparatus 501, performs the above functions defined in the method in the embodiments of the present disclosure.

It should be noted that the computer-readable medium in the present disclosure may be either a computer-readable signal medium or a computer-readable storage medium, or any combination of the two. The computer-readable storage medium may be, for example, but is not limited to, electric, magnetic, optical, electromagnetic, infrared, or semiconductor systems, apparatuses, or devices, or any combination of the above. More specific examples of the computer-readable storage medium may include, but are not limited to: an electrical connection with one or more wires, a portable computer disk, a hard drive, a random access memory (RAM), a read-only memory (ROM), an erasable programmable read-only memory (EPROM or a flash memory), an optical fiber, a portable compact disk read-only memory (CD-ROM), an optical storage device, a magnetic storage device, or any suitable combination of the above. In the present disclosure, the computer-readable storage medium may be any tangible medium including or storing a program, and the program may be used by or in conjunction with an instruction execution system, apparatus, or device. However, in the present disclosure, the computer-readable signal medium may include a data signal propagated in a baseband or as a part of a carrier, where the data signal carries computer-readable program code. The propagated data signal may take various forms, including but not limited to an electromagnetic signal, an optical signal, or any suitable combination of the above. The computer-readable signal medium may also be any computer-readable medium other than the computer-readable storage medium. The computer-readable signal medium may send, propagate, or transmit a program for use by or for use in conjunction with the instruction execution system, apparatus, or device. The program code included in the computer-readable medium may be transmitted by any suitable medium including but not limited to a wire, an optical cable, radio frequency (RF), etc., or any suitable combination of the above.

In some implementations, a client and a server may communicate using any currently known or future-developed network protocols such as a hypertext transfer protocol (HTTP), and may be interconnected with digital data communication in any form or medium (e.g., a communication network). Examples of the communication network include a local area network (“LAN”), a wide area network (“WAN”), an internetwork (e.g., the Internet), a peer-to-peer network (e.g., an ad hoc peer-to-peer network), and any currently known or future-developed network.

The computer-readable medium may be included in the above electronic device; or may also separately exist without being assembled in the electronic device.

The computer-readable medium carries one or more programs. The one or more programs, when executed by the electronic device, cause the electronic device to perform the above method of the present disclosure.

The computer program code for performing the operations of the present disclosure may be written in one or more programming languages or a combination thereof. The programming languages include object-oriented programming languages such as Java, Smalltalk, and C++, and further include conventional procedural programming languages such as “C” language or similar programming languages. The program code may be executed entirely on a user computer, partly on the user computer, as a stand-alone software package, partly on the user computer and partly on a remote computer, or entirely on the remote computer or the server. In the case of involving the remote computer, the remote computer may be connected to the user computer through any type of network, including a local area network (LAN) or a wide area network (WAN), or may be connected to an external computer (e.g., utilizing an Internet service provider for Internet connectivity).

The flowcharts and the block diagrams in the accompanying drawings illustrate the possibly implemented system architecture, functions, and operations of the system, the method, and the computer program product according to the various embodiments of the present disclosure. In this regard, each block in the flowcharts or the block diagrams may represent a module, a program segment, or a part of code, and the module, the program segment, or the part of code includes one or more executable instructions for implementing specified logic functions. It should also be noted that in some alternative implementations, the functions marked in the blocks may also occur in an order different from that marked in the accompanying drawings. For example, two blocks shown in succession may actually be performed substantially in parallel, or may sometimes be performed in a reverse order, depending on functions involved. It should also be noted that each block in the block diagrams and/or the flowcharts, and a combination of the blocks in the block diagrams and/or the flowcharts may be implemented by using a dedicated hardware-based system that performs specified functions or operations, or may be implemented by using a combination of dedicated hardware and computer instructions.

The related units described in the embodiments of the present disclosure may be implemented by software or hardware. The name of the unit does not limit the unit in certain cases.

Herein, the functions described above may be at least partially executed by one or more hardware logic components. For example, without limitation, exemplary hardware logic components that can be used include: a field-programmable gate array (FPGA), an application specific integrated circuit (ASIC), an application specific standard part (ASSP), a system on chip (SOC), a complex programmable logic device (CPLD), etc.

In the context of the present disclosure, a machine-readable medium may be a tangible medium that may include or store a program for use by or for use in conjunction with the instruction execution system, apparatus, or device. The machine-readable medium may be a machine-readable signal medium or a machine-readable storage medium. The machine-readable medium may include, but is not limited to, an electronic, magnetic, optical, electromagnetic, infrared, or semiconductor system, apparatus, or device, or any suitable combination of the above content. More specific examples of the machine-readable storage medium may include an electrical connection based on one or more wires, a portable computer disk, a hard drive, a random access memory (RAM), a read-only memory (ROM), an erasable programmable read-only memory (EPROM or a flash memory), an optical fiber, a portable compact disk read-only memory (CD-ROM), an optical storage device, a magnetic storage device, or any suitable combination of the above content.

According to one or more embodiments of the present disclosure, a cryo-electron microscopy image processing method is provided. The cryo-electron microscopy image processing method includes: obtaining a cryo-electron microscopy image; encoding the cryo-electron microscopy image into a latent variable through an encoder; converting the latent variables into an atomic model structure through a decoder; correcting the atomic model structure using a loss function to obtain a corrected atomic model structure, where the loss function includes a bond length constraint loss function, a clash constraint loss function, and a spring constraint loss function; and converting, through a projector module, the corrected atomic model structure into a density map represented by Gaussian spheres, and projecting the density map to obtain a projection image.

According to one or more embodiments of the present disclosure, the latent variable includes an 8-dimensional vector.

According to one or more embodiments of the present disclosure, the atomic model structure includes an N×3 matrix, where N corresponds to a number of amino acids, and 3 corresponds to spatial coordinates (x, y, z) of the corresponding amino acid.

According to one or more embodiments of the present disclosure, the loss function further includes a reconstruction loss function, which is determined based on a variance between the cryo-electron microscopy image and the projection image.

According to one or more embodiments of the present disclosure, the cryo-electron microscopy image processing method further includes: performing low-frequency filtering on the cryo-electron microscopy image and the projection image before determining the reconstruction loss function.

According to one or more embodiments of the present disclosure, a cutoff frequency for the low-frequency filtering is determined based on the Fourier shell correlation between a reconstruction result of the cryo-electron microscopy image and the density map.

According to one or more embodiments of the present disclosure, the cryo-electron microscopy image processing method further includes: in a case that the atomic model structure is corrected using the spring constraint loss function, calculating variances of lengths of springs between amino acids, and discarding springs whose variances are within a preset percentage when sorted in a descending order.

According to one or more embodiments of the present disclosure, a cryo-electron microscopy image processing apparatus is provided. The cryo-electron microscopy image processing apparatus includes: an image obtaining module, configured to obtain a cryo-electron microscopy image; an encoding module, configured to encode the cryo-electron microscopy image into latent variables through an encoder; a decoding module, configured to convert the latent variables into an atomic model structure through a decoder; a correction module, configured to correct the atomic model structure using a loss function to obtain a corrected atomic model structure, where the loss function includes a bond length constraint loss function, a clash constraint loss function, and a spring constraint loss function; and a projection module, configured to convert, through a projector module, the corrected atomic model structure into a density map represented by Gaussian spheres, and project the density map to obtain a projection image.

According to one or more embodiments of the present disclosure, a terminal is provided, and includes at least one memory and at least one processor, where the at least one memory is used to store program code, and the at least one processor is used to invoke the program code stored in the at least one memory to perform any one of the above methods.

According to one or more embodiments of the present disclosure, a storage medium is provided. The storage medium is used to store program code. The program code is used to perform the above method.

What are described above are only preferred embodiments of the present disclosure and explanations of the technical principles applied. Those skilled in the art should understand that the scope of the disclosure involved in the present disclosure is not limited to the technical solutions formed by specific combinations of the foregoing technical features, and shall also cover other technical solutions formed by any combination of the foregoing technical features or equivalent features thereof without departing from the foregoing concept of disclosure, such as a technical solution formed by replacing the foregoing features with the technical features with similar functions disclosed (but not limited to) in the present disclosure.

Further, although the operations are described in a particular order, it should not be understood as requiring these operations to be performed in the shown particular order or in a sequential order. In certain environments, multitasking and parallel processing may be advantageous. Similarly, although several specific implementation details are included in the above discussion, these specific implementation details should not be interpreted as limitations on the scope of the present disclosure. Some features that are described in the context of separate embodiments may also be implemented in combination in a single embodiment. In contrast, various features described in the context of a single embodiment may also be implemented in a plurality of embodiments separately or in any suitable sub-combination.

Although the subject matter has been described in a language specific to structural features and/or logic actions of the method, it should be understood that the subject matter defined in the appended claims is not necessarily limited to the specific features or actions described above. On the contrary, the specific features and the actions described above are merely example forms for implementing the claims.

I/we claim:

1. A cryo-electron microscopy image processing method, comprising:
obtaining a cryo-electron microscopy image;
encoding the cryo-electron microscopy image into a latent variable through an encoder;
converting the latent variable into an atomic model structure through a decoder;
correcting the atomic model structure using a loss function to obtain a corrected atomic model structure, wherein the loss function comprises a bond length constraint loss function, a clash constraint loss function, and a spring constraint loss function; and
converting, through a projector module, the corrected atomic model structure into a density map represented by Gaussian spheres, and projecting the density map to obtain a projection image.

2. The cryo-electron microscopy image processing method according to claim 1, wherein the latent variable comprises an 8-dimensional vector.

3. The cryo-electron microscopy image processing method according to claim 1, wherein the atomic model structure comprises an N×3 matrix, N corresponds to a number of amino acids, and 3 corresponds to spatial coordinates (x, y, z) of a corresponding amino acid.

4. The cryo-electron microscopy image processing method according to claim 1, wherein the loss function further comprises a reconstruction loss function, and the reconstruction loss function is determined based on a variance between the cryo-electron microscopy image and the projection image.

5. The cryo-electron microscopy image processing method according to claim 4, further comprising:
performing low-frequency filtering on the cryo-electron microscopy image and the projection image before determining the reconstruction loss function.

6. The cryo-electron microscopy image processing method according to claim 5, wherein a cutoff frequency for the low-frequency filtering is determined based on a Fourier shell correlation between a reconstruction result of the cryo-electron microscopy image and the density map.

7. The cryo-electron microscopy image processing method according to claim 1, further comprising:
in a case that the atomic model structure is corrected using the spring constraint loss function, calculating variances of lengths of springs between amino acids, and discarding springs whose variances are within a preset percentage when sorted in a descending order.

8. A terminal, comprising
at least one memory and at least one processor,
wherein the at least one memory is configured to store program code, and the at least one processor is configured to call the program code stored in the at least one memory, and the program code, when executed by the at least one processor, causes the terminal to:
obtain a cryo-electron microscopy image;
encode the cryo-electron microscopy image into a latent variable through an encoder;
convert the latent variable into an atomic model structure through a decoder;
correct the atomic model structure using a loss function to obtain a corrected atomic model structure, wherein the loss function comprises a bond length constraint loss function, a clash constraint loss function, and a spring constraint loss function; and
convert, through a projector module, the corrected atomic model structure into a density map represented by Gaussian spheres, and project the density map to obtain a projection image.

9. The terminal according to claim 8, wherein the latent variable comprises an 8-dimensional vector.

10. The terminal according to claim 8, wherein the atomic model structure comprises an N×3 matrix, N corresponds to a number of amino acids, and 3 corresponds to spatial coordinates (x, y, z) of a corresponding amino acid.

11. The terminal according to claim 8, wherein the loss function further comprises a reconstruction loss function, and the reconstruction loss function is determined based on a variance between the cryo-electron microscopy image and the projection image.

12. The terminal according to claim 11, the program code further causes the terminal:
perform low-frequency filtering on the cryo-electron microscopy image and the projection image before determining the reconstruction loss function.

13. The terminal according to claim 12, wherein a cutoff frequency for the low-frequency filtering is determined based on a Fourier shell correlation between a reconstruction result of the cryo-electron microscopy image and the density map.

14. The terminal according to claim 8, the program code further causes the terminal:
in a case that the atomic model structure is corrected using the spring constraint loss function, calculate variances of lengths of springs between amino acids, and discard springs whose variances are within a preset percentage when sorted in a descending order.

15. A non-transitory storage medium, wherein the non-transitory storage medium is configured to store program code, and the program code, when executed by a processor, causes the processor to:
obtain a cryo-electron microscopy image;
encode the cryo-electron microscopy image into a latent variable through an encoder;
convert the latent variable into an atomic model structure through a decoder;
correct the atomic model structure using a loss function to obtain a corrected atomic model structure, wherein the loss function comprises a bond length constraint loss function, a clash constraint loss function, and a spring constraint loss function; and
convert, through a projector module, the corrected atomic model structure into a density map represented by Gaussian spheres, and project the density map to obtain a projection image.

16. The non-transitory storage medium according to claim 15, wherein the latent variable comprises an 8-dimensional vector.

17. The non-transitory storage medium according to claim 15, wherein the atomic model structure comprises an N×3 matrix, N corresponds to a number of amino acids, and 3 corresponds to spatial coordinates (x, y, z) of a corresponding amino acid.

18. The non-transitory storage medium according to claim 15, wherein the loss function further comprises a reconstruction loss function, and the reconstruction loss function is determined based on a variance between the cryo-electron microscopy image and the projection image.

19. The non-transitory storage medium according to claim 18, the program code further causes the processor:
perform low-frequency filtering on the cryo-electron microscopy image and the projection image before determining the reconstruction loss function.

20. The non-transitory storage medium according to claim 19, wherein a cutoff frequency for the low-frequency filtering is determined based on a Fourier shell correlation between a reconstruction result of the cryo-electron microscopy image and the density map.
